(19) United States
(12) Patent Application Publication
(10) Pub. No.: US 2025/0294850 A1
(43) Pub. Date: Sep. 18, 2025

(54) MEMORY DEVICE AND MANUFACTURING METHOD THEREOF

(71) Applicant: NANYA TECHNOLOGY CORPORATION, New Taipei city (TW)

(72) Inventor: Ying-Cheng CHUANG, New Taipei City (TW)

(21) Appl. No.: 18/602,039

(22) Filed: Mar. 12, 2024

(51) Int. Cl. H01L 29/423; H01L 21/265; H01L 29/51; H01L 29/66; H01L 29/78; H10B 12/00

(52) U.S. Cl. CPC H10D 64/513; H01L 21/26586; H10D 30/025; H10D 30/63; H10D 64/681; H10B 12/34

(57) ABSTRACT

A memory device includes a substrate, a first word line layer, a second word line layer, a gate dielectric layer and source/drain regions. The first word line layer is in the substrate. The second word line layer is in the substrate and over the first word line layer. The gate dielectric layer lines the first word line layer and the second word line layer. The source/drain regions is on the substrate and on opposite sides of the second word line layer, in which one of the source/drain regions includes a first fluorine-containing region adjacent to the second word line layer.

### BACKGROUND

### Field of Disclosure

The present disclosure relates to a memory device and a manufacturing method thereof.

### Description of Related Art

A dual work function word line structure is a kind of common word line structure in a memory device. The dual work function word line structure includes two conductive layers with different work functions, and the source/drain regions are formed at the sides of the conductive layer with lower work function to reduce the gate-induced drain leakage (GIDL) in the memory device. However, the GIDL needs to be further reduced to enhance the performance of the memory device.

### SUMMARY

Some embodiments of the present disclosure provides a memory device, includes a substrate, a first word line layer, a second word line layer, a gate dielectric layer and source/drain regions. The first word line layer is in the substrate. The second word line layer is in the substrate and over the first word line layer. The gate dielectric layer lines the first word line layer and the second word line layer. The source/drain regions is on the substrate and on opposite sides of the second word line layer, in which one of the source/drain regions includes a first fluorine-containing region adjacent to the second word line layer.

In some embodiments, a bottom of the first fluorine-containing region is substantially level with a top of the first word line layer.

In some embodiments, the memory device further includes a cap layer over the second word line layer, in which the first fluorine-containing region is adjacent to the cap layer.

In some embodiments, the memory device further includes a barrier layer between the cap layer and the second word line layer.

In some embodiments, a portion of the gate dielectric layer above a top surface of the first word line layer includes fluorine.

In some embodiments, a fluorine concentration of a portion of the gate dielectric layer lining the first word line layer is lower than a fluorine concentration of a portion of the gate dielectric layer lining the second word line layer.

In some embodiments, a portion of one of the source/drain regions does not include fluorine.

In some embodiments, the memory device further includes a barrier layer between the first word line layer and the second word line layer.

In some embodiments, the memory device further includes an isolation structure in the substrate, in which the isolation structure includes a second fluorine-containing region.

In some embodiments, the second word line layer is made of polysilicon.

Some embodiments of the present disclosure provide a manufacturing method of a memory device, includes forming a trench in a substrate, forming a gate dielectric layer lining the trench in the substrate, forming a first word line layer over the gate dielectric layer and in the trench, after forming the first word line layer, performing an implantation process to form a first fluorine-containing region in the substrate, and after the implantation process is complete, forming a second word line layer in the trench and over the first word line.

In some embodiments, the implantation process is performed by implanting ions into the substrate at a tilted angle with respect to a top surface of the substrate.

In some embodiments, during the implantation process, fluorine is implanted into a portion of the gate dielectric layer exposed through the trench.

In some embodiments, the manufacturing method further includes forming a cap layer in the trench and over the second word line, in which the first fluorine-containing region is adjacent to the cap layer.

In some embodiments, the manufacturing method further includes forming a barrier layer over the second word line layer, in which the barrier layer is formed between forming the cap layer.

In some embodiments, the manufacturing method further includes forming a barrier layer over the first word line layer, in which the barrier layer is formed between forming the second word line layer

In some embodiments, the first fluorine-containing region is adjacent to the second word line layer.

In some embodiments, a bottom of the first fluorine-containing region is substantially level with a top of the first word line layer.

In some embodiments, a work function value of the second word line layer is lower than a work function value of the first word line layer.

In some embodiments, the manufacturing method further includes forming an isolation structure in the substrate, in which during performing the implantation process, a second fluorine-containing region is formed in the isolation structure.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a circuit diagram of a memory device in some embodiments of the present disclosure.

FIGS. 2-14 illustrate cross-sections of a manufacturing method of a memory device in some embodiments of the present disclosure.

### DETAILED DESCRIPTION

Some embodiments of the present disclosure are related to a memory device including a fluorine-containing region adjacent to the word line. The fluorine in the fluorine-containing region can be used to reduce the gate-induced drain leakage (GIDL) in the memory device.

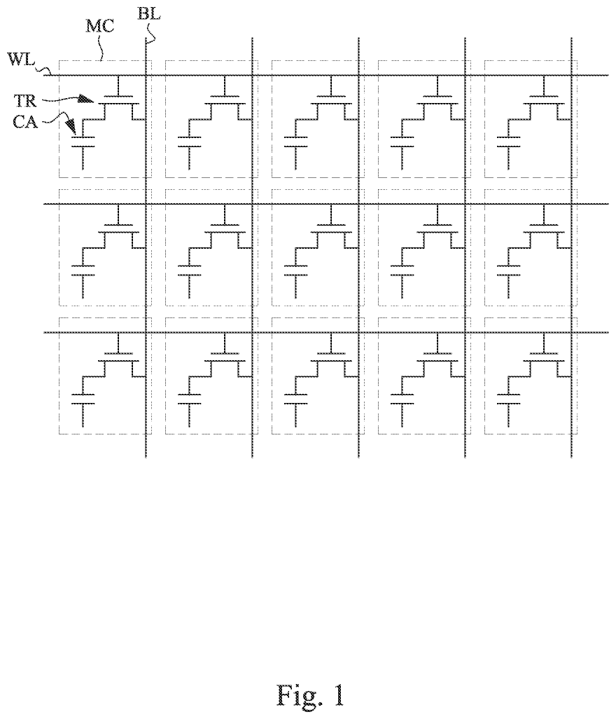

FIG. 1 illustrates a circuit diagram of a memory device in some embodiments of the present disclosure. Referring to FIG. 1, the memory device (e.g., dynamic random access memory, DRAM) may include a plurality of memory cells MC. A typical DRAM memory cell MC incorporates a capacitor CA and a transistor TR in which the capacitor CA temporarily store data based on the charged state of the capacitor CA. A bit line BL is electrically connected to a source/drain region of the transistor TR, and a word line WL is electrically connected to a gate region of the transistor TR. The capacitor CA is electrically connected to the other source/drain region of the respective transistor TR. The word line WL in the present disclosure is a dual work function word line. The later discussion will emphasize the manufacturing process of the transistor TR and the word line WL, and the manufacturing method of the bit line BL and the capacitor CA will not be mentioned.

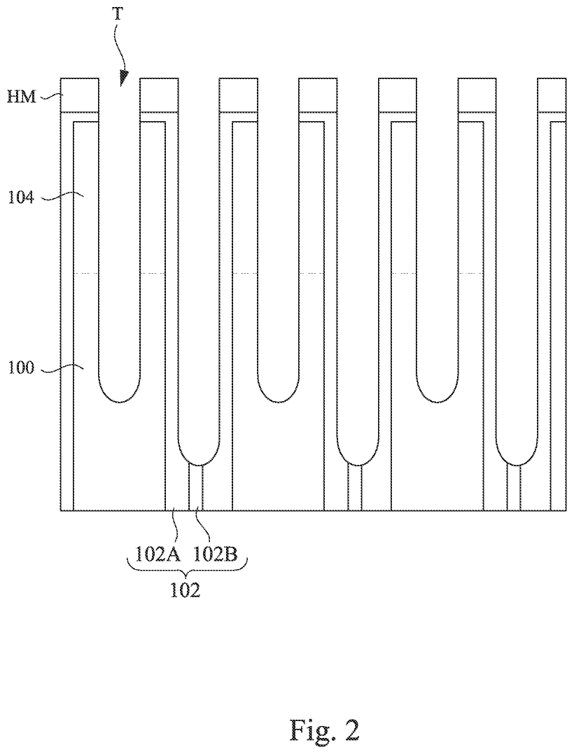

FIGS. 2-14 illustrate cross-sections of a manufacturing method of a memory device in some embodiments of the present disclosure. Referring to FIG. 2, a substrate 100 is provided, and isolation structures 102 are formed in the substrate 100. The substrate 100 includes doped regions 104 at the upper portion of the substrate 100. The substrate 100 and the doped regions 104 have different conductivity type. For example, if the substrate 100 is an n-type substrate, then the doped regions 104 are p-type regions. If the substrate 100 is a p-type substrate, then the doped regions 104 are n-type regions. The p-type substrate and the p-type region include the P-type dopants, such as boron, gallium or aluminum. The n-type substrate and the n-type region include the n-type dopant, such as phosphorus, arsenic, or antimony. The doped regions 104 serve as the source/drain regions in the transistor TR in FIG. 1, and the substrate 100 serves as the channel region in the transistor TR in FIG. 1. In some embodiments, the substrate 100 may be made of semiconductor material, such as silicon. In some embodiments, the isolation structures 102 may be made of dielectric material, such as silicon oxide, silicon nitride, or combinations thereof. For example, each of the isolation structures 102 may include a first portion 102A of the isolation structure made of silicon oxide and a second portion 102B of the isolation structure made of silicon nitride.

Subsequently, a hard mask layer HM is formed over the substrate 100, and trenches T are formed in the substrate 100 by etching the substrate 100 through the hard mask layer HM. The bottom of the trench T is lower than the bottom of the doped region 104. In some embodiments, the trenches T are further formed in the isolation structures 102, and the bottom of the trench T in the isolation structure 102 is lower than the bottom of the trench T in the substrate 100.

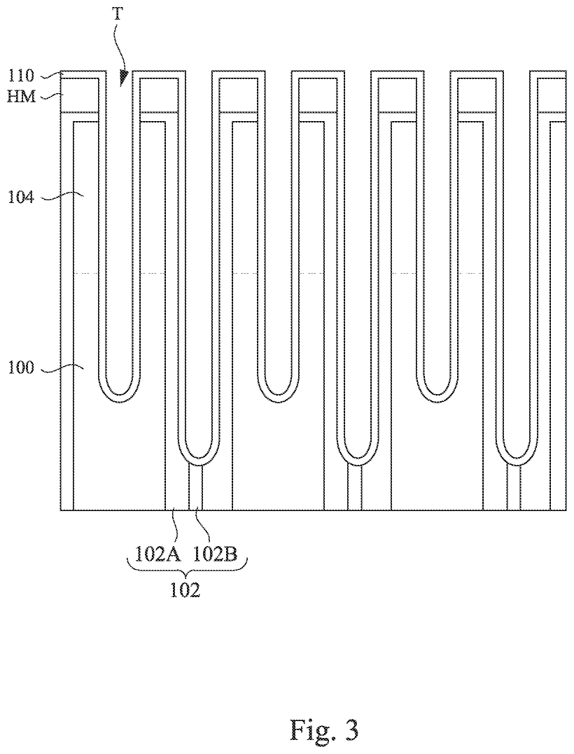

Referring to FIG. 3, a gate dielectric layer 110 is formed lining the trenches T in the substrate 100 and the trenches T in the isolation structures 102. The gate dielectric layer 110 is further along the top surface and the sidewall of the hard mask layer HM. In some embodiments, the gate dielectric layer 110 may be formed by atomic layer deposition (ALD), in situ steam generation (ISSG) or combinations thereof. In some embodiment, the gate dielectric layer 110 is made of silicon oxide.

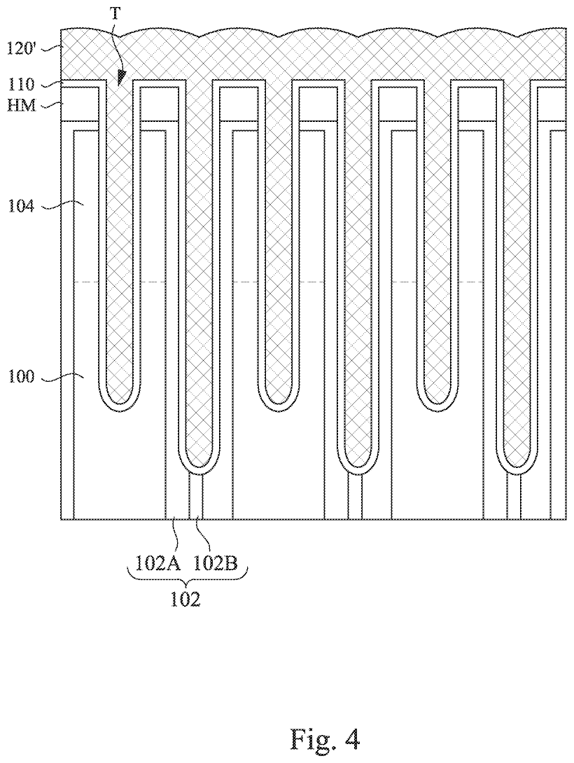

Referring to FIG. 4, a first word line material layer 120′ is formed overfilling the trenches T. That is, the first word line material layer 120′ not only fills the trenches T, but also covers the hard mask layer HM and the gate dielectric layer 110. The first word line material layer 120′ is formed by a conductive material. In some embodiments, the first word line material layer 120′ is formed by titanium nitride (TiN).

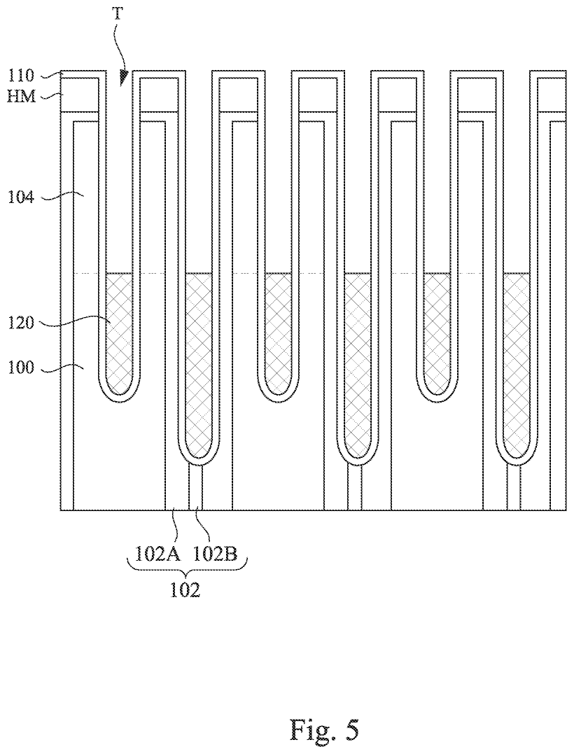

Referring to FIG. 5, an etching back process is performed on the first word line material layer 120′, so as to lower the top surfaces of the first word line material layer 120′, and the remaining portions of the first word line material layer 120′ are referred to as first word line layers 120. In some embodiments, the top surface of the first word line layer 120 is not higher than the bottom of the doped region 104.

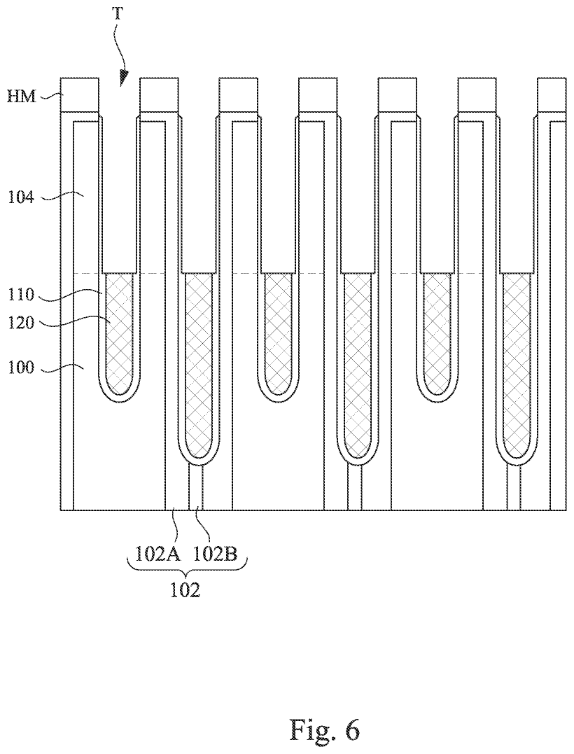

Referring to FIG. 6, a cleaning process is performed on the first word line layers 120, so as to remove residues on first word line layers 120, such as native oxide. In some embodiments, because the gate dielectric layer 110 also includes oxide, during the cleaning process, portions of the gate dielectric layer 110 along the top surface and the sidewall of the hard mask layer HM are removed, and portions of the gate dielectric layer 110 along the isolation structures 102 and the substrate 100 are thinned. This will results in that a thickness of the portion of the gate dielectric layer 110 protruding from the first word line layer 120 is less than a thickness of the gate dielectric layer 110 covered by the first word line layer 120.

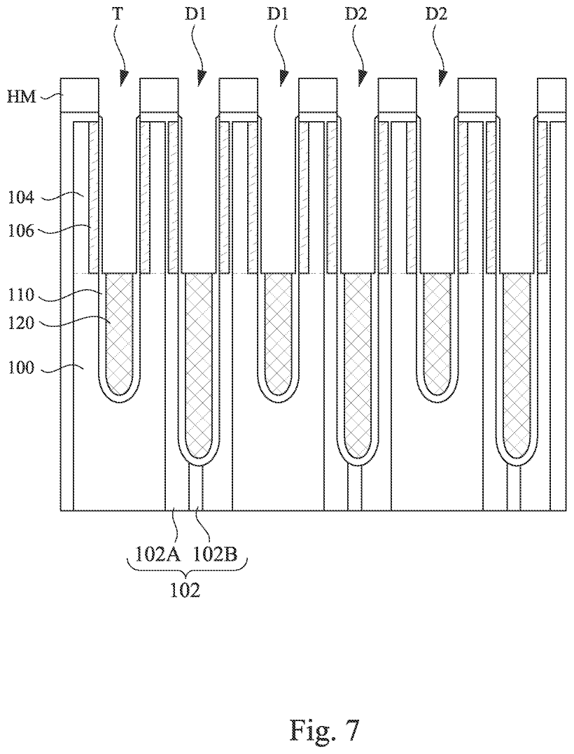

Referring to FIG. 7, after forming the first word line layers 120, an implantation process is performed to form fluorine-containing regions 106 in the substrate 100. The implantation process is performed by implanting fluorine into the substrate 100 at a tilted angle with respect to a top surface of the substrate 100. The fluorine-containing regions 106 are in the doped regions 104 of the substrate 100 and near the gate dielectric layers 110, and a portion of the doped regions 104 does not includes fluorine (such as the portion of the doped regions 104 far away from the second word line layer 140). Since the fluorine-containing regions 106 are formed after forming the doped regions 104, the fluorine-containing regions 106 also include same dopants as those in the doped regions 104. Since the fluorine-containing regions 106 are formed after forming the first word line layers 120, the location of the fluorine-containing regions 106 is precisely controlled. For example, the bottom of the fluorine-containing region 106 is substantially level with the top of the first word line layer 120. Therefore, a short channel effect may be reduced since the fluorine atoms in the fluorine-containing region 106 do not diffuse into the channel region (such as the substrate 100 covered by the first word line layer 120) of the transistor. The fluorine concentration of the portions of the substrate 100 covered by the first word line layers 120 is lower than the fluorine concentration of the portions of the substrate 100 adjacent to the second word line layers 140. The bottom of the fluorine-containing region 106 is also higher than the bottom of the first word line layer 120.

During the implantation process, fluorine-containing regions 106 are also formed in the isolation structures 102, and the bottom of the fluorine-containing region 106 of the isolation structure 102 is also level with the top of the first word line layer 120. In some embodiments, fluorine atoms are also be implanted into the portions of gate dielectric layer 110 exposed through the trenches T, such that the portions of the gate dielectric layer 110 also include fluorine after the implantation process is complete. For example, the thinner portions of the gate dielectric layer 110 protruding from the first word line layers 120 (i.e. the portions of the gate dielectric layer 110 above a top surface of the first word line layer 120) may be exposed to the implantation process, and thus may include fluorine as a result of the implantation process. On the other hand, the thicker portions of the gate dielectric layer 110 may be protected by the first word line layers 120, and thus such portions may be free of fluorine (or has a lower fluorine concentration than the thinner portions of the gate dielectric layer 110). That is, a fluorine concentration of the portions of the gate dielectric layer 110 lining the first word line layers 120 are lower than a fluorine concentration of the portions of the gate dielectric layers 110 lining the second word line layers 140.

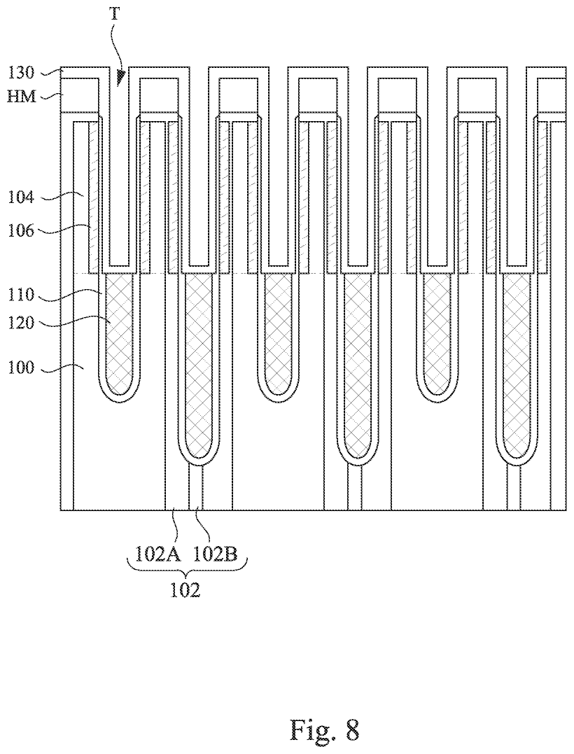

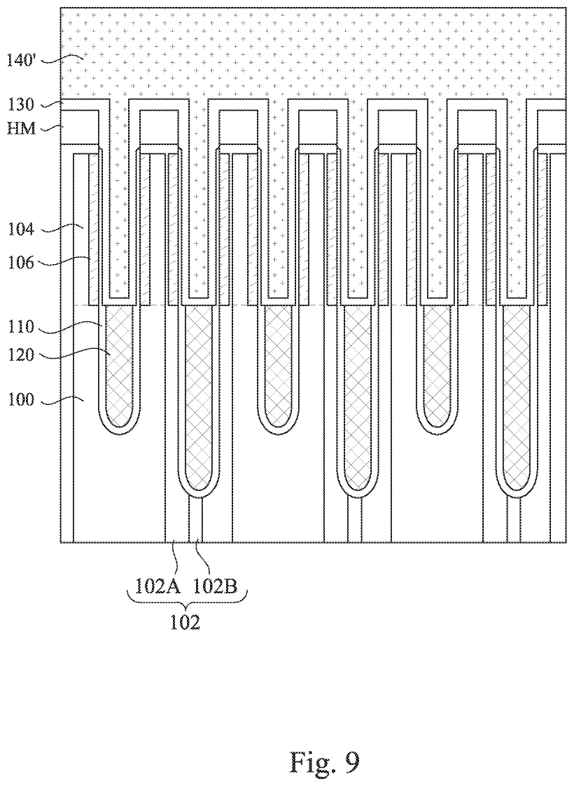

Referring to FIG. 8, a barrier layer 130 is formed lining the trenches T and over the first word line layers 120. The barrier layer 130 is further along the top surface and the sidewall of the hard mask layer HM. The barrier layer 130 is formed of silicon oxide. Referring to FIG. 9, an etching back process is performed on the second word line material layer 140′, so as to lower the top surfaces of the second word line material layer 140′, and the remaining portions of the second word line material layer 140′ are referred to as second word line layers 140. In some embodiments, the work function value of the second word line material layer 140′ is lower than the work function value of the first word line layer 120. In some embodiments, the second word line material layer 140′ is made of polysilicon. In some embodiments, each first word line layer 120 and its corresponding second word line layer 140 can be referred to as a word line structure.

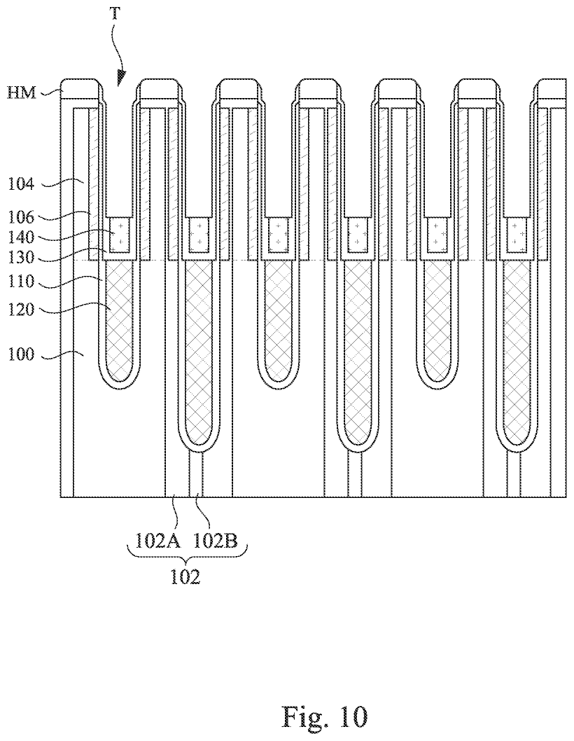

Referring to FIG. 10, after forming the second word line layers 140, a cleaning process is performed on the second word line layers 140, so as to remove residues on second word line layers 140, such as native oxide. In some embodiments, because the barrier layer 130 also includes oxide. Accordingly, during the cleaning process, portions of the barrier layer 130 along the top surface and the sidewall of the hard mask layer HM are removed, and portions of the barrier layer 130 along the isolation structures 102 and the substrate 100 are thinned. In some embodiments, an observable interface may present between the barrier layer 130 and the gate dielectric layer 110, since the gate dielectric layer 110 protruding from the second word line layer 140 includes fluorine after the implantation process in FIG. 7. On the other hand, the barrier layer 130 is formed after the implantation process, so the barrier layer 130 is free of fluorine (or has a lower fluorine concentration than the gate dielectric layer 110). In some other embodiments, the barrier layer 130 along the isolation structures 102 and the substrate 100 are also removed. In some embodiments, portions of the barrier layer 130 lining the second word line layer 140 may also serve as the gate dielectric layer.

After forming the second word line layer 140, the fluorine-containing region 106 is adjacent to the second word line layer 140. The fluorine-containing regions 106 are closer to the second word line layers 140 than the doped regions 104 are, and the fluorine-containing regions 106 are used to reduce the GIDL. Specifically, the GIDL is easily to generate at the overlap region between the doped region 104 and the second word line layer 140. The fluorine-containing region 106 is formed between the doped region 104 and the second word line layer 140, and the fluorine in the fluorine-containing regions 106 is used to trap the electron-hole pairs in the doped regions 104. That is, the amount of the electron-hole pairs near the gate dielectric layer 110 is reduced, thereby reducing GIDL.

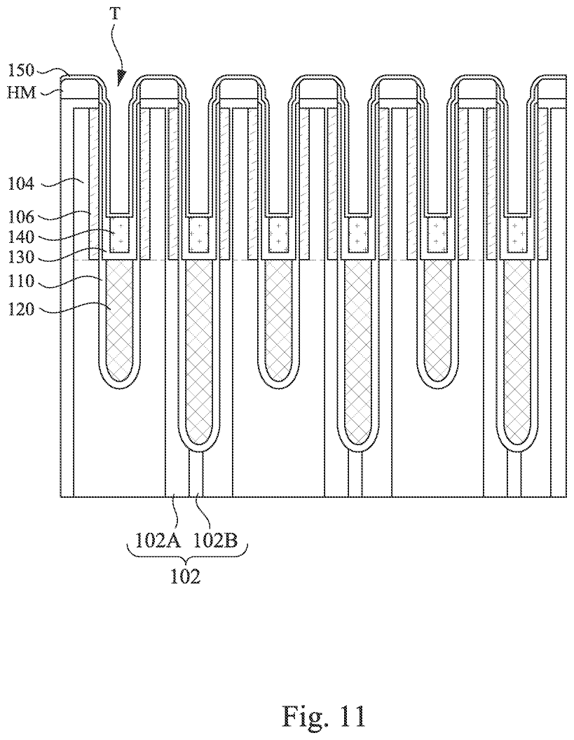

Referring to FIG. 11, a barrier layer 150 is formed lining the trenches T and over the second word line layers 140. The barrier layer 150 is further along the top surface and the sidewall of the hard mask layer HM. The barrier layer 150 is formed of silicon oxide.

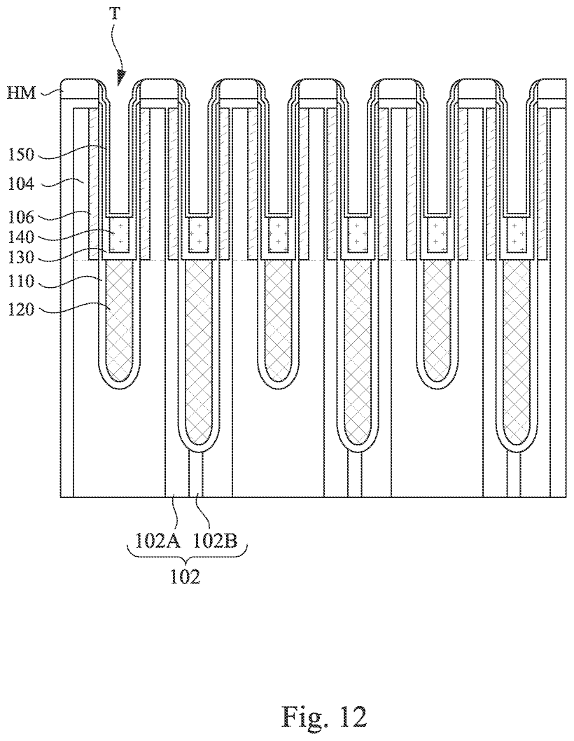

Referring to FIG. 12, an etching process is performed to remove portions of the barrier layer 150 covering the top surface of the hard mask layer HM, such that a top surface of the hard mask layer HM is exposed.

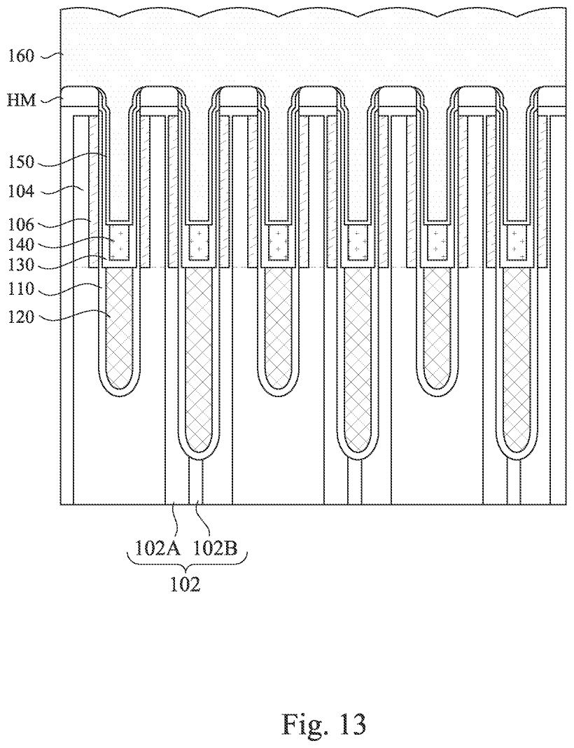

Referring to FIG. 13, a cap layer 160 is formed in the trenches T and over the second word line layers 140 and the barrier layers 150. After forming the cap layer 160, the fluorine-containing region 106 is adjacent to the cap layer 160. In some embodiments, the cap layer 160 is made of dielectric material. In some embodiments, the cap layer 160 is made of silicon nitride.

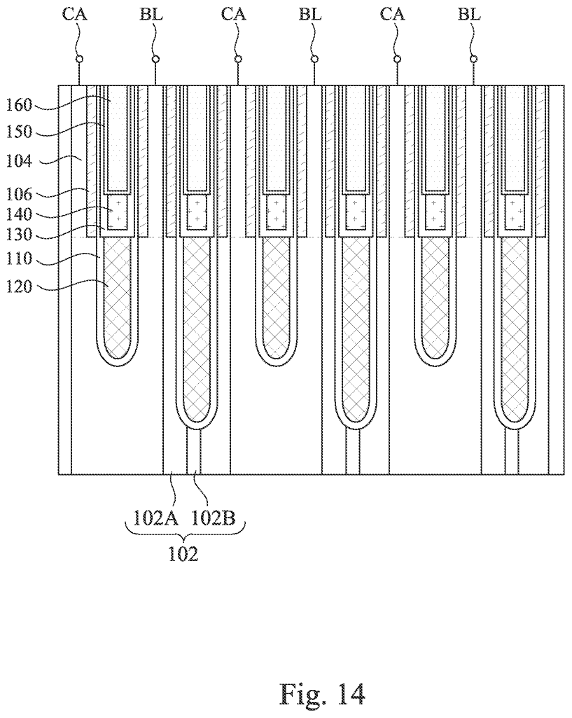

Referring to FIG. 14, a planarization process, such as CMP, is performed on the cap layer 160 until the doped regions 104 of the substrate 100 are exposed. During the planarization process, the hard mask layer HM may also be removed. Afterwards, a bit line BL and a capacitor CA may be formed electrically connected to the doped regions 104.

The resulting memory device is illustrated in FIG. 14. The memory device includes a substrate 100, a first word line layer 120, a second word line layer 140, a gate dielectric layer 110 and source/drain regions 104. The first word line layer 120 is in the substrate 100. The second word line layer 140 is in the substrate 100 and over the first word line layer 120. The source/drain regions 104 are on the substrate 100 and on opposite sides of the second word line layer 140. One of the source/drain regions 104 includes a fluorine-containing region 106 adjacent to the second word line layer 140. A work function of the second word line layer 140 may be lower than a work function of the first word line layer 120, and the first word line layer 120 and the second word line layer 140 forms a dual work function word line structure. In such word line structure, doped regions 104 used as source/drain regions are formed adjacent to the second word line layer 140 with lower work function to reduce GIDL. In some embodiments, the first word line layer 120 is made of titanium nitride, and the second word line layer 140 is made of polysilicon. However, the present disclosure is not limited thereto. The fluorine-containing region 106 adjacent to the second word line layer 140 may be used to further reduce the GIDL. Specifically, the fluorine atom in the fluorine-containing region 106 is used to trap the electron-hole pairs in a doped region 104 of the substrate 100. That is, the amount of the electron-hole pairs near the gate dielectric layer 110 is reduced, and the GIDL is reduced. In some embodiments, the memory device further includes an isolation structure 102 in the substrate 100, and the isolation structure 102 also includes a fluorine-containing region 106.

The memory device further includes a cap layer 160, a barrier layer 130, and a barrier layer 150. The cap layer 160 is over the second word line layer 140, in which the fluorine-containing region 106 is further adjacent to the cap layer 160. The barrier layer 150 is between the cap layer 160 and the second word line layer 140. The barrier layer 130 is between the first word line layer 120 and the second word line layer 140.

As mentioned above, the memory device in the present disclosure has an advantage of reducing GIDL of a dual work function word line structure. A fluorine-containing region is formed near the gate dielectric layer along the word line layer with lower work function. The fluorine-containing region is used to trap the electron-hole pairs near the gate dielectric layer, and reduce the amount of the electron-hole pairs near the gate dielectric layer. Therefore, GIDL is reduced in the memory device in the present disclosure.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A memory device, comprising:
a substrate;
a first word line layer in the substrate;
a second word line layer in the substrate and over the first word line layer;
a gate dielectric layer lining the first word line layer and the second word line layer; and
source/drain regions on the substrate and on opposite sides of the second word line layer, wherein one of the source/drain regions comprises a first fluorine-containing region adjacent to the second word line layer.

2. The memory device of claim 1, wherein a bottom of the first fluorine-containing region is substantially level with a top of the first word line layer.

3. The memory device of claim 1, further comprising:
a cap layer over the second word line layer, wherein the first fluorine-containing region is adjacent to the cap layer.

4. The memory device of claim 3, further comprising:
a barrier layer between the cap layer and the second word line layer.

5. The memory device of claim 1, wherein a portion of the gate dielectric layer above a top surface of the first word line layer comprises fluorine.

6. The memory device of claim 1, wherein a fluorine concentration of a portion of the gate dielectric layer lining the first word line layer is lower than a fluorine concentration of a portion of the gate dielectric layer lining the second word line layer.

7. The memory device of claim 1, wherein a portion of one of the source/drain regions does not comprises fluorine.

8. The memory device of claim 1, further comprising:
a barrier layer between the first word line layer and the second word line layer.

9. The memory device of claim 1, further comprising:
an isolation structure in the substrate, wherein the isolation structure comprises a second fluorine-containing region.

10. The memory device of claim 1, wherein the second word line layer is made of polysilicon.

11. A manufacturing method of a memory device, comprising:
forming a trench in a substrate;
forming a gate dielectric layer lining the trench in the substrate;
forming a first word line layer over the gate dielectric layer and in the trench;
after forming the first word line layer, performing an implantation process to form a first fluorine-containing region in the substrate; and
after the implantation process is complete, forming a second word line layer in the trench and over the first word line layer.

12. The manufacturing method of claim 11, wherein the implantation process is performed by implanting ions into the substrate at a tilted angle with respect to a top surface of the substrate.

13. The manufacturing method of claim 11, wherein during the implantation process, fluorine is implanted into a portion of the gate dielectric layer exposed through the trench.

14. The manufacturing method of claim 11, further comprising:
forming a cap layer in the trench and over the second word line layer, wherein the first fluorine-containing region is adjacent to the cap layer.

15. The manufacturing method of claim 14, further comprising:
forming a barrier layer over the second word line layer, wherein the barrier layer is formed between forming the cap layer.

16. The manufacturing method of claim 11, further comprising:
forming a barrier layer over the first word line layer, wherein the barrier layer is formed between forming the second word line layer.

17. The manufacturing method of claim 11, wherein the first fluorine-containing region is adjacent to the second word line layer.

18. The manufacturing method of claim 11, wherein a bottom of the first fluorine-containing region is substantially level with a top of the first word line layer.

19. The manufacturing method of claim 11, wherein a work function value of the second word line layer is lower than a work function value of the first word line layer.

20. The manufacturing method of claim 11, further comprising:
forming an isolation structure in the substrate, wherein during performing the implantation process, a second fluorine-containing region is formed in the isolation structure.
